(19) United States
(12) Patent Application Publication
(10) Pub. No.: US 2014/0085803 A1
(43) Pub. Date: Mar. 27, 2014

(54) MOUNTING DEVICE FOR HARD DISK DRIVE

(71) Applicant: ZHENG-HENG SUN, Tu-Cheng (TW)

(72) Inventor: ZHENG-HENG SUN, Tu-Cheng (TW)

(21) Appl. No.: 13/649,647

(22) Filed: Oct. 11, 2012

(30) Foreign Application Priority Data
Sep. 25, 2012 (CN) 2012103600747

(51) Int. Cl. H05K 7/14

(52) U.S. Cl. 361/679.33

(57) ABSTRACT

A mounting device for a hard disk drive (HDD) includes a fixing plate and two fixing members. Two protrusions and a blocking piece adjacent to one of the protrusions protrude from the fixing plate. Each fixing member includes a sidewall, and a top wall and a bottom wall perpendicularly extending from opposite sides of the sidewall. The top walls are fastened to a bottom wall of the HDD. Each bottom wall defines an engaging hole. Each engaging hole includes a first hole and a second hole communicating with the first hole. A projection protrudes from the sidewall of one of the fixing members away from the corresponding bottom wall. The HDD is slid toward the blocking piece, to allow the protrusions to enter and engage in the corresponding second holes from the corresponding first holes. The projection is blocked by the blocking piece.

### BACKGROUND

1. Technical Field

The present disclosure relates to a device for mounting a hard disk drive (HDD).

2. Description of Related Art

Many HDDs are screwed to brackets in computers, so the HDDs are rigidly connected to chassis of the computers, which means any vibrations or shocks to the chassis are easily transferred to the HDDs. When an HDD is operating at a high speed, such vibrations may harm the HDDs.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device together with a hard disk drive (HDD), wherein the mounting device includes a fixing member.

FIG. 2 is an enlarged view of the fixing member of FIG. 1, but viewed from another perspective.

FIG. 3 is an assembled view of the HDD and the fixing member of FIG. 1, but viewed from another perspective.

FIG. 4 is an assembled, isometric view of FIG. 1, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

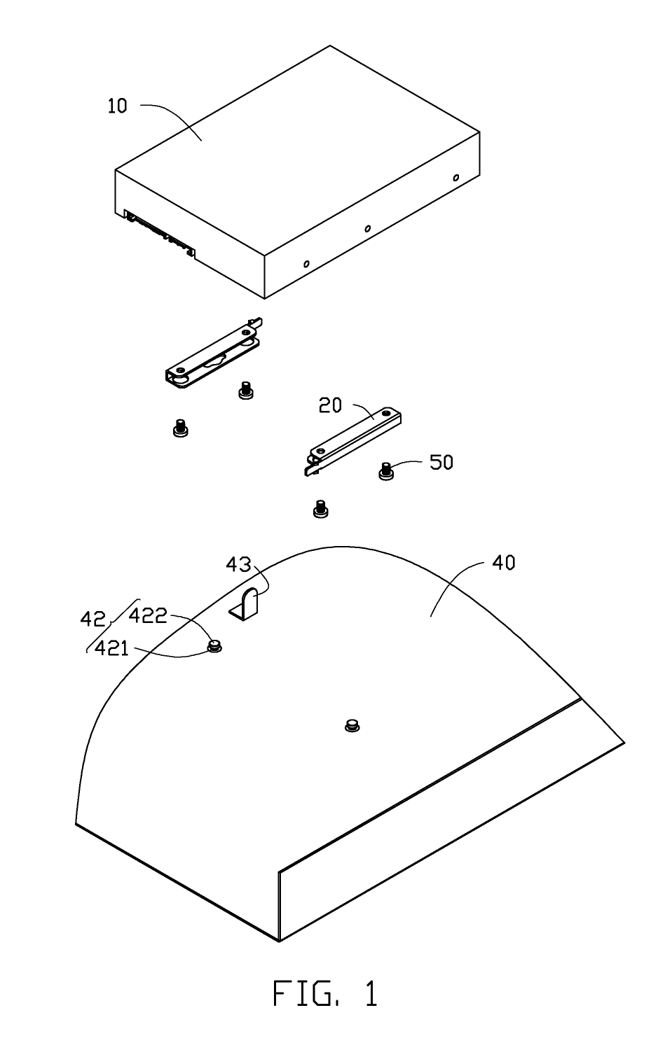

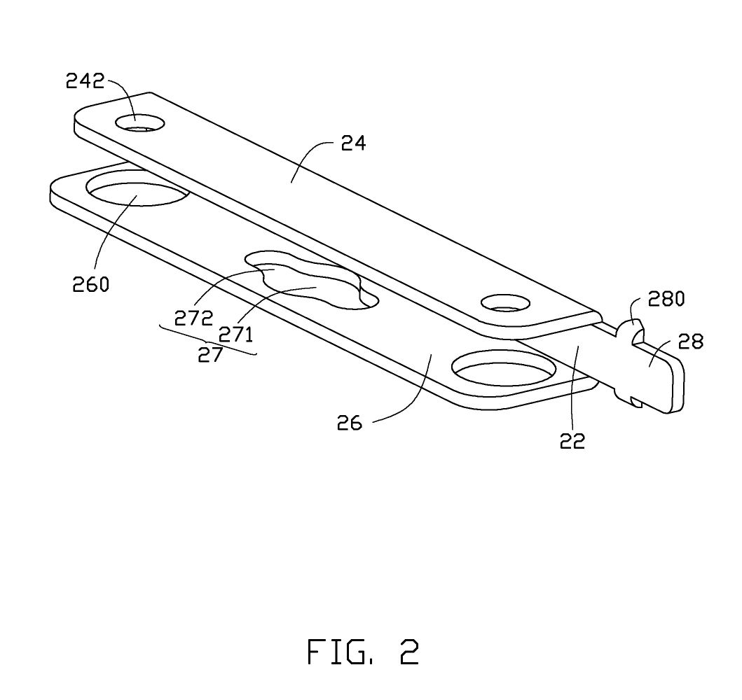

FIGS. 1 and 2 show an exemplary embodiment of a mounting device for a hard disk drive (HDD) 10. Four mounting holes (not shown) are defined in a bottom wall of the HDD 10. The mounting device includes a fixing plate 40, and two fixing members 20.

Two opposite protrusions 42 protruding up from the fixing plate 40. Each protrusion 42 includes a columnar neck portion 421 extending up from the fixing plate 40 and a round head 422 extending from a top of the neck portion 421. A diameter of the neck portion 421 is less than a diameter of the head portion 422. A blocking piece 43 protrudes up from the fixing plate 40, beside a side of one of the protrusions 42.

Each fixing member 20 is substantially U-shaped, and includes a long sidewall 22, a top wall 24 and a bottom wall 26 perpendicularly extending from opposite sides of the sidewall 22, and an extension piece 28 extending from an end of the sidewall 22. Two through holes 242 are defined in opposite ends of the top wall 24. The bottom wall 26 defines two receiving holes 260 respectively aligning with the through holes 242 and an engaging hole 27 between the receiving holes 260. The diameter of the receiving holes 260 is greater than the diameter of the through holes 242. A screwdriver is capable of extending through the receiving holes 260. The engaging hole 27 includes a first hole 271 and two second holes 272 communicating with opposite ends of the first hole 271. A width of the first hole 271 is greater than a width of the second holes 272. Two projections 280 protrude from opposite sides of the extension piece 28, away from the bottom wall 26 and the top wall 24.

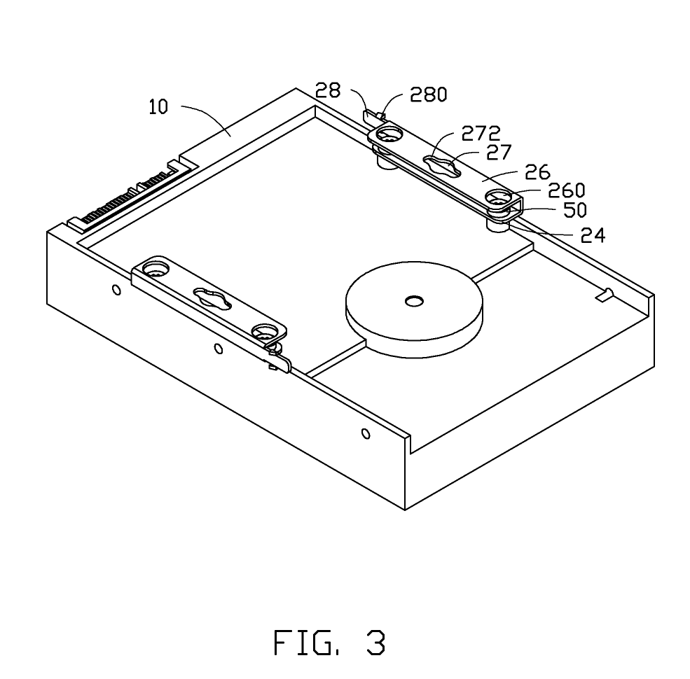

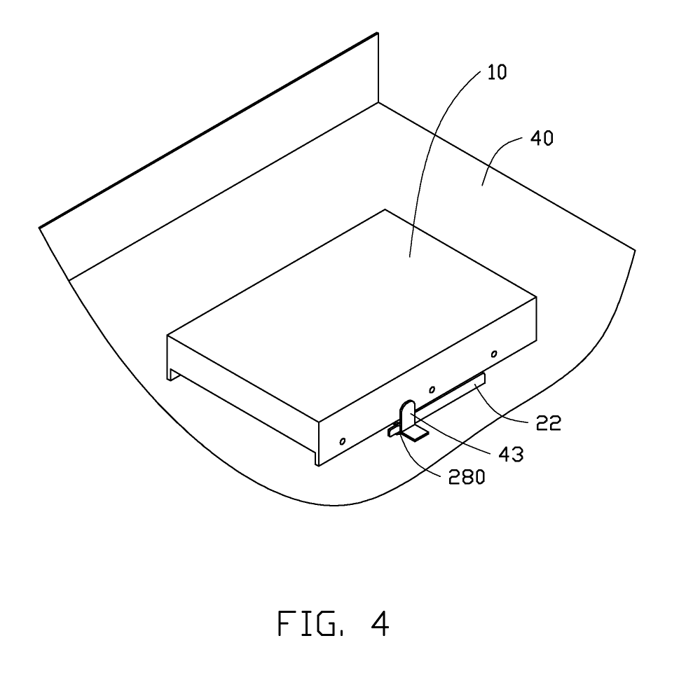

FIGS. 3 and 4 show in assembly, the top walls 24 abut the bottom wall of the HDD 10, and the through holes 242 align with the corresponding mounting holes of the HDD 10. Four screws 50 pass through the corresponding receiving holes 260 and extend through the corresponding through holes 242, and then engage in the corresponding mounting holes, to fix the fixing members 20 to the bottom of the HDD 10. The fixing members 20 are placed above the fixing plate 40, and the first holes 271 are aligned with the corresponding protrusions 42. The fixing members 20 are manipulated down to abut the fixing plate 40, to gather the protrusions 42 into the first holes 271. The HDD 10 together with the fixing members 20 is slid to make the fixing members 20 move toward the blocking piece 43. The projections 280 of the fixing member 20 adjacent to the blocking piece 43 slide along a surface of the blocking piece 43 facing the protrusions 42, to deform the corresponding extension piece 28, until the necks 421 engage in the corresponding second holes 272. The heads 422 abut the corresponding bottom walls 26. The deformed extension piece 28 is then restored, therefore, the corresponding projections 280 are blocked by an end of the blocking piece 28 opposite to the protrusions 42.

The HDD 10 is fixed to the fixing plate 40 by the U-shaped fixing members 20, with a certain distance existing between the fixing plate 40 and the HDD 10. When the HDD 10 and the fixing plate 40 are subjected to vibrations or shocks, the fixing members 20 can be deformed to absorb at least part of the vibration energy.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for a hard disk drive (HDD), comprising:
a fixing plate, two protrusions and a blocking piece adjacent to one of the protrusions protruding from the fixing plate; and
two fixing members each comprising a sidewall, and a top wall and a bottom wall perpendicularly extending from opposite sides of the sidewall, the top walls for being fixed to a bottom of the HDD, the bottom wall of each fixing member defining an engaging hole, the engaging hole comprising a first hole and a second hole communicating with the first hole, the first hole having a greater size than the second hole, one of the fixing members further comprising a projection protruding from the sidewall away from the corresponding bottom wall;
wherein when the HDD is operable to slide toward the blocking piece to allow the protrusions to respectively enter and then engage in the second holes from the corresponding first holes, the projection is blocked by the blocking piece.

2. The mounting device of claim 1, wherein each protrusion comprises a neck portion extending up from the fixing plate and a head portion extending from a top of the neck, the neck engages in a corresponding one of the second holes, the head abuts a top surface of the corresponding bottom wall.

3. The mounting device of claim 1, wherein the fixing member further comprises an extension piece extending from the sidewall, the projection protrudes from the extension piece and is capable of being deformed while sliding along the blocking piece.

4. The mounting device of claim 1, further comprising two fasteners, wherein the top wall of each fixing member defines two through holes, the bottom wall of the fixing member defines two receiving holes respectively in alignment with the through holes of the top wall, a diameter of the receiving holes is greater than a diameter of the through holes, the fasteners are respectively passed through the corresponding receiving holes and extended through the corresponding through holes to be engaged in the HDD.
